(19) United States
(12) Patent Application Publication
(10) Pub. No.: US 2012/0205805 A1
(43) Pub. Date: Aug. 16, 2012

(54) SEMICONDUCTOR DEVICE AND METHOD OF MANUFACTURING THE SAME

(76) Inventor: Chan Sun HYUN, Gyeonggi-do (KR)

(21) Appl. No.: 13/396,977

(22) Filed: Feb. 15, 2012

(30) Foreign Application Priority Data
Feb. 16, 2011 (KR) 10-2011-0013554

(51) Int. Cl. H01L 23/48; H01L 21/265; H01L 21/768

(52) U.S. Cl. 257/751; 257/774; 438/653; 438/533; 257/E23.011; 257/E21.577; 257/E21.334

(57) ABSTRACT

A semiconductor device includes a first interlayer dielectric layer formed over a semiconductor substrate, contact holes formed to penetrate the first interlayer dielectric layer, contact plugs formed within the contact holes, respectively, and spacers formed to partially cover upper sidewalk of the contact plugs within the contact holes.

### CROSS-REFERENCE TO RELATED APPLICATION

Priority to Korean patent application number 10-2011-0013554 filed on Feb. 16, 2011, the entire disclosure of which is incorporated by reference herein, is claimed.

### BACKGROUND

Exemplary embodiments relate to a semiconductor device and a method of manufacturing the same and, more particularly, to a semiconductor device in which structures formed over and under an insulating layer, respectively, are electrically coupled through contact plugs penetrating the insulating layer and a method of manufacturing the same.

A semiconductor device may include a plurality of conductive patterns and insulating layers stacked over a semiconductor substrate. The semiconductor device further includes contact plugs formed to penetrate an insulating layer in order to electrically couple lower conductive structures formed under the insulating layer and upper conductive structures formed over the insulating layers, with the insulating layer interposed therebetween. The contact plugs for electrically coupling the lower structures and the upper structures are described in more detail by taking contact plugs for electrically coupling the drain regions and the bit lines of a NAND flash memory device as an example.

FIG. 1 is a cross-sectional view showing drain contact plugs for electrically coupling the drain regions and the bit lines of a NAND flash memory device.

Referring to FIG. 1, the NAND flash memory device includes a plurality of memory strings, each including a drain select transistor, a source select transistor, and a plurality of memory cells coupled in series between the drain select transistor and the source select transistor. Meanwhile, the memory strings are electrically coupled to a page buffer unit for supplying a voltage for storing the data of the memory cells through the bit lines 19. Each of the bit lines 19 is electrically coupled to the drain region 5 of the memory string through a drain contact plug 11. More specifically, an upper structure (e.g., the bit line 19) formed above a first interlayer dielectric layer 7 may be electrically coupled to a lower structure (e.g., the drain region 5) formed below the first interlayer dielectric layer 7 through the drain contact plug 11 penetrating the first interlayer dielectric layer 7.

The drain regions 5 are formed by implanting impurities into the active regions of a semiconductor substrate 1 which are defined/bounded by isolation layers 3. The drain contact plugs 11 are formed by a process of forming the at least one first interlayer dielectric layer 7 over the semiconductor substrate 1 including the drain regions 5, a process of forming drain contact holes 9 penetrating the first interlayer dielectric layer 7 by etching part of the first interlayer dielectric layer 7 so that the drain regions 5 are exposed, and a process of filling the drain contact holes 9 with a conductive material. The bit lines 19 may be formed using a damascene scheme. If a damascene scheme is used, the bit lines 19 may be formed by a process of stacking an etch-stop layer 13 and a second interlayer dielectric layer 15 over the first interlayer dielectric layer 7 in which the drain contact plugs 11 are formed, a process of etching part of the second interlayer dielectric layer 15 to expose the etch-stop layer 13 and etching the exposed etch-stop layer 13 to form trenches 17 through which the drain contact plugs 11 are exposed, and a process of filling the trenches 17 with a conductive material.

As the patterns of the semiconductor device are narrowed to 30 nm or less in order to increase the degree of integration of the semiconductor devices, an interval between the adjacent drain contact plugs 11 is narrowed. Accordingly, the shortest distance L1 between the drain contact plugs 11 and the bit lines 19 may be smaller than a set value where an overlay margin of the drain contact plugs 11 and the bit lines 19 is insufficient. Consequently, leakage is generated due to a short between the drain contact plugs 11 and the bit lines 19 that are to be insulated from each other and causes the semiconductor device to malfunction.

FIG. 2 is a cross-sectional view of another NAND flash memory device capable of reducing a short within the NAND flash memory device shown in FIG. 1. The remaining elements other than the drain contact plugs 21 and the spacers 20 of the NAND flash memory device shown in FIG. 2 are the same as those of FIG. 1. The same elements of FIG. 2 as those of FIG. 1 are assigned the same reference numerals as those of FIG. 1 and formed using the same method as that of FIG. 1.

Referring to FIG. 2, to reduce shorts between the drain contact plugs 21 and the bit lines 19 that are to be insulated from each other, after the drain contact holes 9 are formed, the spacers 20 are formed on the entire sidewalls of the drain contact holes 9 by using an insulating layer. Next, the drain contact plugs 21 are formed by filling a conductive material within the drain contact holes 9 in which the respective spacers 20 are formed. Accordingly, the shortest distance L2 between the drain contact plugs 21 and the bit lines 19 can be increased by the width of the spacer 20. Consequently, a short between the drain contact plugs 21 and the bit lines 19 that are to be insulated from each other can be prevented because an overlay margin of the drain contact plugs 21 and the bit lines 19 is increased.

However, in forming the spacers 20 on the sidewalls of the drain contact holes 9, the additional process of forming the spacers 20 adds complexity to the overall process. Furthermore, contact resistance of the drain contact plug 21 is reduced because the width of the bottom of the drain contact plug 21 is narrowed by the width of the spacer 20.

### BRIEF SUMMARY

Exemplary embodiments relate to a semiconductor device and a method of manufacturing the same, which are capable of improving resistance of a contact plug penetrating an insulating layer.

A semiconductor device according to an aspect of this disclosure includes a first interlayer dielectric layer formed over a semiconductor substrate, contact holes formed to penetrate the first interlayer dielectric layer, contact plugs formed within the contact holes, respectively, and spacers formed to partially cover upper sidewalls of the contact plugs within the contact holes.

A semiconductor device according to another aspect of this disclosure includes a first interlayer dielectric layer formed over a semiconductor substrate, contact holes formed to penetrate the first interlayer dielectric layer, conductive layers formed within the contact holes, barrier metal layers formed to cover lower sidewalk of the conductive layers and bottom surfaces of the conductive layers within the contact holes, and spacers formed to partially cover upper sidewalk of the conductive layers within the contact holes.

A method of manufacturing a semiconductor device according to yet another aspect of this disclosure includes forming a first interlayer dielectric layer on a semiconductor substrate, forming contact holes penetrating the first interlayer dielectric layer, forming contact plugs within the contact holes, wherein upper sidewalls of the contact plugs are recessed, and forming spacers partially covering the upper sidewalls of the contact plugs.

### BRIEF DESCRIPTION OF THE DRAWINGS

FIG. 1 is a cross-sectional view showing drain contact plugs for electrically coupling the drain regions and the bit lines of a NAND flash memory device.

FIG. 2 is a cross-sectional view of another NAND flash memory device capable of preventing an occurrence of a short within the NAND flash memory device shown in FIG. 1.

FIG. 3 is a plan view of a semiconductor device according to an exemplary embodiment of this disclosure.

FIGS. 4A to 4G are cross-sectional views of the semiconductor device taken along line I-I′ of FIG. 3 in order to illustrate a method of manufacturing the semiconductor device according to an exemplary embodiment of this disclosure.

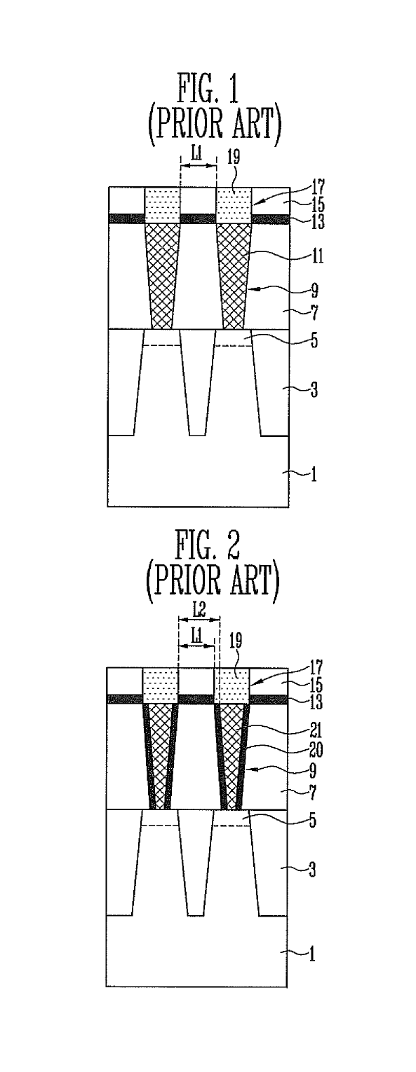

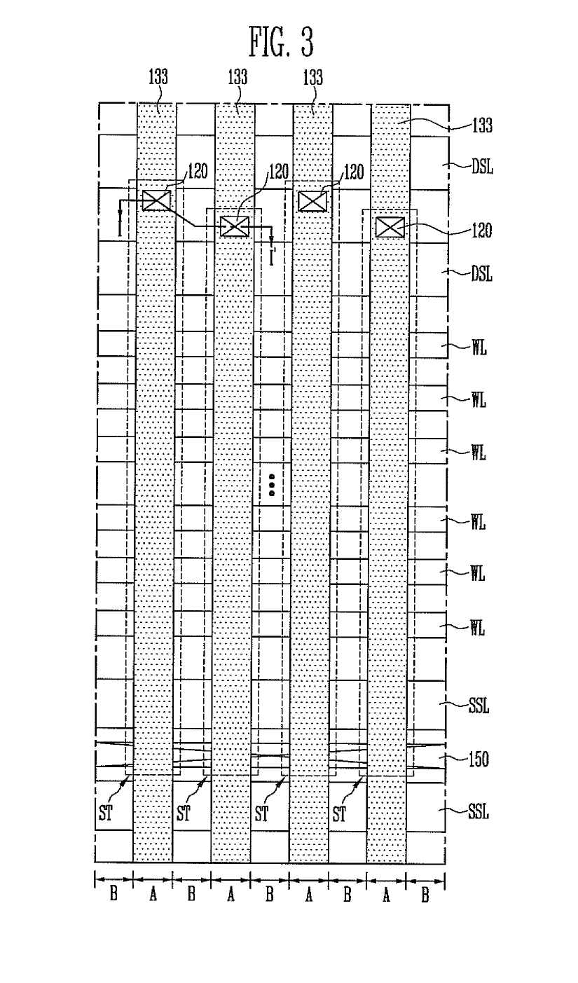

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the exemplary embodiments of the disclosure.

FIG. 3 is a plan view of a semiconductor device according to an exemplary embodiment of this disclosure. In particular, FIG. 3 shows, for example, a NAND flash memory device.

Referring to FIG. 3, the cell array of the NAND flash memory device according to the exemplary embodiment of this disclosure includes isolation regions B in which trenches or isolation layers are formed and active regions A defined by the isolation regions B. The isolation regions B and the active regions A are alternately formed in parallel. Furthermore, drain select lines DSL, source select lines SSL, and word lines WL are formed over a semiconductor substrate so that they cross the isolation regions B and the active regions A. The plurality of word lines WL are formed between the drain select line DSL and the source select line SSL which are adjacent to each other.

In general, the drain select lines DSL are adjacent to each other, and the source select lines SSL are adjacent to each other. Impurities are implanted into the active region A between the select lines DSL and SSL and the word lines WL to form junctions. Here, the junction formed between the drain select lines DSL becomes the drain region of a memory string ST, and the junction formed between the source select lines SSL becomes the source region of the memory string ST.

A drain select transistor formed at the intersection of the drain select line DSL and the active region A, a source select transistor formed at the intersection of the source select line SSL and the active region A, and a plurality of memory cells formed at the intersections of the word lines WL between the drain select transistor and the source select transistor are coupled in series to form the one memory string ST. Each memory string ST is electrically coupled to a bit line BL corresponding to a drain contact plug 120 through the drain contact plug 120 and is electrically coupled to a metal wire (not shown) to which a common source voltage is supplied through a source contact line 150. The bit lines BL are formed over the active regions A and formed in parallel to the active regions A. Furthermore, the bit lines BL couple the memory strings ST and a page buffer unit (not shown) for supplying voltage necessary to store data of the memory cells.

Each of the drain contact plugs 120 is formed over the active region A between the drain select lines DSL. Furthermore, the drain contact plug 120 is formed to penetrate at least one first interlayer dielectric layer covering lower structures, such as the drain select line DSL, the source select line SSL, the word line WL, the isolation region B, the active region A, and the source contact line 150, and is coupled to the drain region formed in a surface of the active region A. Furthermore, the drain contact plug 120 is formed within a contact hole through which the drain region is exposed by etching a first interlayer dielectric layer. In order to secure etch margin in an etch process for forming the contact holes, the contact holes between the drain select lines DSL are arranged in a zigzag pattern. Accordingly, the drain contact plugs 120 coupled to the drain regions arranged in a row along the drain select line DSL are also arranged in a zigzag pattern. Consequently, a failure where the adjacent drain contact plugs 120 are coupled to each other because due to the short distance therebetween can be prevented.

The bit lines BL are formed in the respective active regions A. Furthermore, the bit lines BL penetrate an etch-stop layer and a second interlayer dielectric layer, covering the drain contact plugs 120, so that the top surfaces of the drain contact plugs 120 are exposed. The bit lines BL are formed within respective trenches which are formed in the same direction as the active regions A.

Meanwhile, the source contact line 150 is formed within a trench which is formed to expose isolation regions B and the source regions between the source select lines SSL. Here, the trench is formed in the same direction as the source select line SSL. Accordingly, the source contact line 150 formed within the trench is electrically coupled to the source regions between the source select lines SSL.

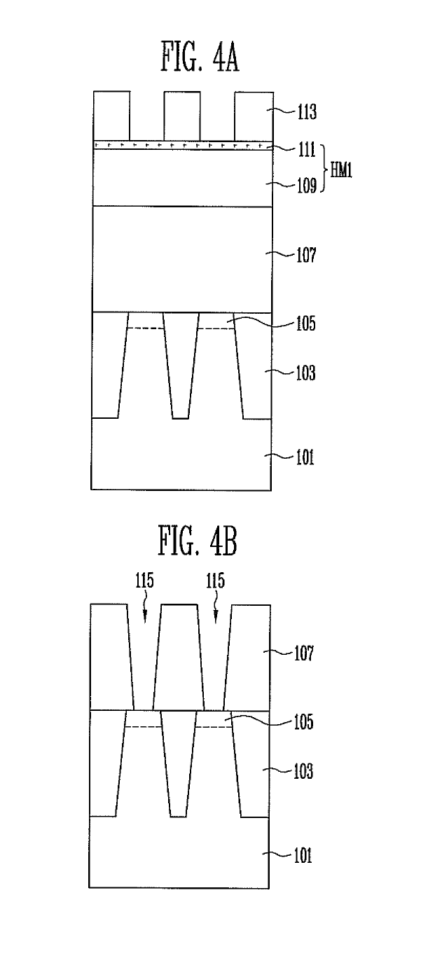

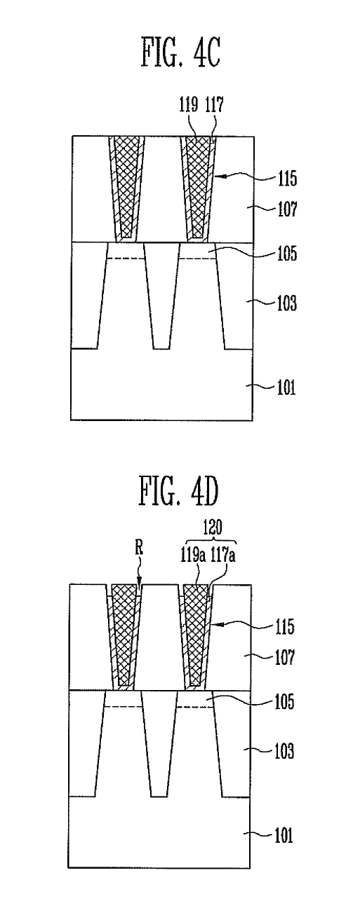

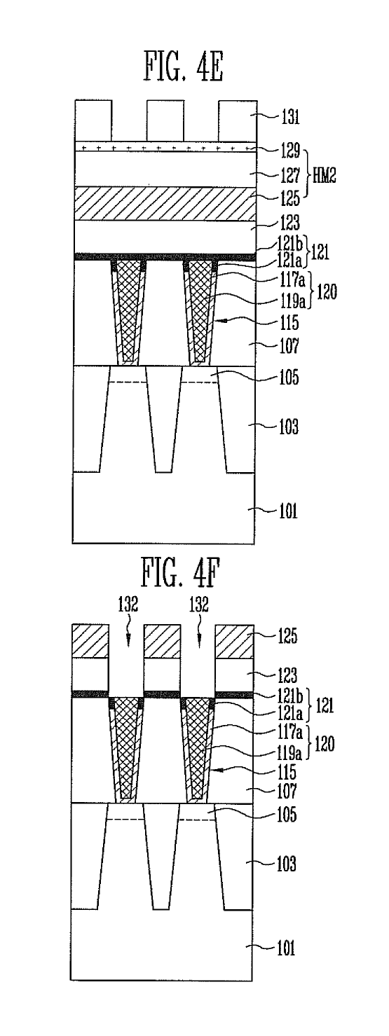

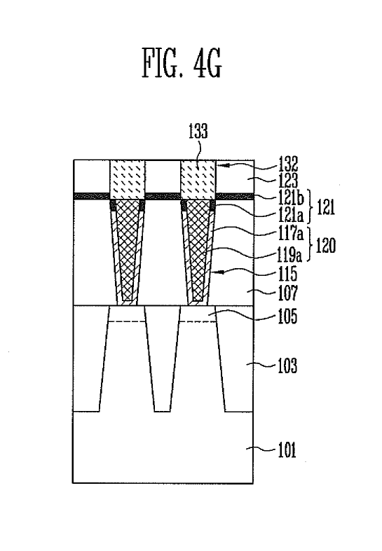

FIGS. 4A to 4G are cross-sectional views of the semiconductor device taken along line I-I′ of FIG. 3 in order to illustrate a method of manufacturing the semiconductor device according to an exemplary embodiment of this disclosure.

Referring to FIG. 4A, there is provided the semiconductor substrate 101 in which junctions, such as drain regions 105, are formed. An example of a detailed process of forming the junctions of a NAND flash memory device is described below.

First, a tunnel insulating layers and a conductive layer for floating gates are deposited over the semiconductor substrate 101. A plurality of isolation mask patterns is formed on the conductive layer. The isolation regions B (FIG. 3) of the semiconductor substrate 101 are exposed by removing the conductive layer and the tunnel insulating layer exposed between the isolation mask patterns. Next, trenches are formed in the semiconductor substrate 101 by etching the isolation regions B, and the trenches are filled with an insulating material. The insulating material is polished by a polishing process, such as chemical mechanical polishing (CMP), so that the isolation mask patterns are exposed. Next, the isolation mask patterns are removed, and isolation layers 103 having a target height are formed by controlling the height of the insulating material using an etch process. The active regions A of the semiconductor substrate 101 are separated from each other with the isolation layer 103 interposed therebetween. A dielectric layer and a conductive layer for control gates are deposited. Before depositing the conductive layer for control gates, contact holes through which the conductive layer for floating gates is exposed are formed in the dielectric layer of regions where the select lines DSL and SSL will be formed. Next, gate hard mask patterns are formed on the conductive layer for control gates. The word lines WL and the select lines DSL and SSL are formed by removing the conductive layer for control gates, the dielectric layer, and the conductive layer for floating gates between the gate hard mask patterns. Next, cell junctions, source regions, and drain regions 105 are formed by implanting impurities into the active regions A (FIG. 3) between the word lines WL and the select lines DSL and SSL.

At least one first interlayer dielectric layer 107 is formed over the drain regions 105. The first interlayer dielectric layer 107 is formed to cover the lower structures 105 (e.g., DSL, SSL, WL, and 105). The first interlayer dielectric layer 107 is commonly formed of an oxide layer. A first hard mask layer HM1 is formed on the first interlayer dielectric layer 107. According to an example, the first hard mask layer HM1 is made of material having a different etch selectivity from that of the first interlayer dielectric layer 107. The first hard mask layer HM1 may have stack structure of an amorphous carbon layer (ACL) 109 and a SiON layer 111. First photoresist patterns 113 are formed on the first hard mask layer HM1. The first photoresist patterns 113 are used to expose regions where contact holes 115 will be formed in a subsequent process.

Referring to FIG. 4B, the first interlayer dielectric layer 107 is exposed by removing the first hard mask layer HM1 exposed between the first photoresist patterns 113. The contact holes 115 through which the drain regions 105 are exposed and which penetrate the first interlayer dielectric layer 107 are formed by removing the exposed first interlayer dielectric layer 107. The contact holes 115 through which the drain regions 105 are exposed become drain contact holes. Next, the remaining first photoresist pattern 113 and the remaining first hard mask layer HM1 are removed.

Referring to FIG. 4C, a first conductive layer 117 is formed on a surface of the contact holes 115 and a surface of the first interlayer dielectric layers 107. A second conductive layer 119 is formed on the first conductive layer 117, so that the contact holes 115 are filled with the second conductive layer 119.

The first conductive layer 117 and the second conductive layer 119 are made of conductive materials. According to an example, the first conductive layer 117 and the second conductive layer 119 are made of materials having a high etch selectivity with respect to each other for an etch material used in a subsequent etch process for removing a part of the first conductive layer 117 which is formed between the sidewall of the contact hole 115 and the second conductive layer 119 in order to form recess regions R (refer to FIG. 4D). Here, if the second conductive layer 119 includes metal, the first conductive layer 117 may be a barrier metal layer for preventing the metal of the second conductive layer 119 from being diffused into the first interlayer dielectric layers 107. For example, if the second conductive layer 119 is made of tungsten (W), the first conductive layer 117 may have a stack structure of a titanium (Ti) layer and a titanium nitride (TiN) layer for preventing the diffusion of tungsten (W). According to an example, the first conductive layer 117 is formed to a thickness of 100 Å to 250 Å in order to secure a sufficient overlay margin of the contact plugs 120 and the bit lines BL when the bit lines BL are subsequently formed and to secure resistance of the contact plugs 120 to be subsequently formed.

Next, the first and the second conductive layers 117 and 119 on a top surface of the first interlayer dielectric layers 107 are removed by a polishing process, such as chemical mechanical polishing (CMP) so that the first interlayer dielectric layers 107 are exposed. Consequently, the first and the second conductive layers 117 and 119 remain only within the contact holes 115.

Referring to FIG. 4D, part of the first conductive layer 117 formed between the sidewall of the contact hole 115 and the sidewall of the second conductive layer 119 is removed by using an etch material having a high etch selectivity for the first conductive layer 117 with respect to the first interlayer dielectric layers 107 and the second conductive layers 119. For example, if the first interlayer dielectric layer 107 is formed of an oxide layer, the second conductive layer 119 is formed of a tungsten (W) layer, and the first conductive layer 117 has a stack structure of a titanium (Ti) layer and a titanium nitride (TiN) layer, the first conductive layer 117 may be etched by using an etch gas in which BCl₃ and Cl₂, having a high etch selectivity for the first conductive layer 117 with respect to the tungsten (W) layer and the oxide layer, are mixed or may be etched by using a Cl₂ etch gas. Accordingly, the second conductive layer 119 and the first interlayer dielectric layer 107 are not etched while the first conductive layer 117 is etched and thus more protruded than the first conductive layer 117 after the etching to thus form a protrusion unit 119a. Next, the recess regions R are formed in regions from which the first conductive layer 117 has partially been removed to thus form capping unit 117a. The etching degree of the first conductive layer 117 may be varied depending on different design needs.

The drain contact plugs 120, each including capping units 117a and a protrusion unit 119a, are formed as the result of the etch process of the first conductive layer 117. Here, the capping units 117a are formed on the sidewalls of the contact holes 115 and at the bottom of the contact holes 115 below the recess regions R. The protrusion units 119a are formed to fill the contact holes 115 outside the recess regions R protrudes/extends beyond the capping units 117a. The drain contact plugs 120 are formed on the drain regions 105 and coupled to the respective drain regions 105. Meanwhile, the bottom of the contact hole 115 is filled with the contact plug 120 outside the recess regions R to thus secure the width of the bottom of the drain contact plug 120.

Referring to FIG. 4E, a material layer 121 is formed on the drain contact plugs 120 and the first interlayer dielectric layers 107 to fill the recess regions R. According to an example, the material layer 121 is made of material having a different etch selectivity from those of the first interlayer dielectric layers 107 and of a second interlayer dielectric layer 123 to be subsequently formed. The material layer 121 may be a nitride layer. Part of the material layer 121 filling the recess regions R becomes spacers 121a, and part of the material layer 121 formed on the first interlayer dielectric layers 107 and the protrusion units 119a becomes etch-stop layers 121b for preventing an excessive etching of the first interlayer dielectric layers 107 in a subsequent etch process.

Next, the second interlayer dielectric layer 123 is formed on the material layer 121. The second interlayer dielectric layer 123 may be an oxide layer. A second hard mask layer HM2 is formed on the second interlayer dielectric layer 123. According to an example, the second hard mask layer HM2 may be made of material having a different etch selectivity from the second interlayer dielectric layer 123. The second hard mask layer HM2 may have a stack structure of a polysilicon layer 125, an amorphous carbon layer (ACL) 127, and a SiON layer 129. Second photoresist patterns 131 are formed on the second hard mask layer HM2. The second photoresist patterns 131 open regions where trenches 132 (FIG. 4F) will be formed in a subsequent process.

Referring to FIG. 4F, the second interlayer dielectric layer 123 is exposed by removing the second hard mask layer HM2 exposed between the second photoresist patterns 131. The exposed second interlayer dielectric layer 123 is removed by an etch process. Here, the etch process of removing the second interlayer dielectric layer 123 is stopped when the material layer 121 is exposed. The drain contact plugs 120 are exposed by removing the exposed material layer 121 using an etch process. Consequently, the trenches 132 through which the respective drain contact plugs 120 are exposed are formed to penetrate the second interlayer dielectric layer 123 and the material layer 121. The remaining material layers 121 include the spacers 121a filling the recess regions R and the etch-stop layers 121b between the second interlayer dielectric layers 123 and the first interlayer dielectric layers 107. When the trenches 132 are formed, the spacers 121a not overlapping with the trenches 132 may be coupled to the etch-stop layers 121b and remain intact after the etching.

As described above, according to the present disclosure, an additional process for forming the spacers 121a separate from the forming of the etch-stop layers 121b is not necessary because the spacers 121a are formed of the material layer 121 for forming the etch-stop layers 121b. Accordingly, a process of manufacturing the semiconductor device can be simplified.

Referring to FIG. 4G, after the remaining second hard mask layers 125 are removed, the trenches 132 are filled with a conductive material. The conductive material may be formed of a copper (Cu) layer having a low resistance. Next, the conductive material formed on top surfaces of the second interlayer dielectric layers 123 is removed by a polishing process, such as chemical mechanical polishing (CMP) so that the second interlayer dielectric layers 123 are exposed. Consequently, the conductive material remains, for example, only within the trenches 132 and thus becomes metal lines 133 (i.e., conductive patterns). The metal lines 133 are formed to penetrate the second interlayer dielectric layer 123 and the material layer 121 and coupled to the respective drain contact plugs 120. The metal lines 133 coupled to the drain regions 105 through the drain contact plugs 120 become the bit lines BL of the NAND flash memory device.

The spacers 121a according to this disclosure are not formed on the entire sidewalls of the contact holes 115, but are formed on, for example, only the circumferences of the upper sidewalls (i.e., the upper sidewalk of the contact holes 115) of the protrusion units 119a that protrudes beyond the capping units 117a. Furthermore, the entire bottom surfaces of the contact holes 115 are filled with the drain contact plugs 120. Consequently, although part of the top of the drain contact plug 120 is reduced by the width of the spacer 121a, the width of the bottom of the contact plug 120 can be secured. Accordingly, contact resistance of the drain contact plug 120 can be increased. Furthermore, since the spacers 121a are formed on the upper sidewalk of the drain contact plugs 120, the distance between the drain contact plugs 120 to the neighboring bit lines 133 that are to be insulated from each other can be increased by the width of the spacer 121a. Accordingly, an overlay margin of the drain contact plugs 120 and the bit lines 133 corresponding to the width of the spacer 121a can be secured.

The structure in which the bit lines 133 and the drain regions 105 are electrically coupled through the drain contact plugs 120 has been illustrated. Exemplary embodiments of the present disclosure, however, may also be applied to the case in which conductive wires under the contact plugs and conductive wires over the contact plugs are electrically coupled through the contact plugs. Furthermore, the exemplary embodiments of the present disclosure may also be applied to the case in which the contact plugs are formed in line form.

As described above, according to this disclosure, the spacers are not formed on the entire sidewalls of the contact plugs but are formed on, for example, only the upper sidewalls of the contact plugs. Accordingly, resistance of the contact plug can be secured because the width of the bottom of the contact plug can be secured. Furthermore, since the spacers are formed on the upper sidewalls of the contact plugs, an overlay margin of the contact plugs that are to be insulated from each other and the conductive patterns formed on the contact plugs that are to be insulated from each other can be secured by the width of the spacer.

In addition, according to this disclosure, since the spacers and the etch-stop layers are formed of the same material layer using the same process, an additional process of forming the spacers becomes unnecessary. Accordingly, the number of processes can be reduced to thus reduce manufacturing costs.

What is claimed is:

1. A semiconductor device, comprising:
a first interlayer dielectric layer formed over a semiconductor substrate;
contact holes formed to penetrate the first interlayer dielectric layer;
contact plugs formed within the contact holes, respectively; and
spacers formed to partially cover upper sidewalls of the contact plugs within the contact holes.

2. The semiconductor device of claim 1, further comprising:
an etch-stop layer formed on the first interlayer dielectric layer and formed of a material layer identical with the spacers;
a second interlayer dielectric layer formed on the etch-stop layer; and
metal lines formed to penetrate the second interlayer dielectric layer and the etch-stop layer and coupled to the contact plugs, respectively.

3. The semiconductor device of claim 2, wherein the spacers and the etch-stop layer are formed of a material layer having a different etch selectivity from the first and the second interlayer dielectric layers.

4. The semiconductor device of claim 2, wherein the semiconductor substrate includes drain regions of a NAND flash memory device in which impurities are implanted,
wherein the metal lines are bit lines of the NAND flash memory device.

5. A semiconductor device, comprising:
a first interlayer dielectric layer formed over a semiconductor substrate;
contact holes formed to penetrate the first interlayer dielectric layer;
conductive layers formed within the contact holes;
barrier metal layers formed to cover lower sidewalls of the conductive layers and bottom surfaces of the conductive layers within the contact holes; and
spacers formed to partially cover upper sidewalls of the conductive layers within the contact holes.

6. The semiconductor device of claim 5, further comprising:
an etch-stop layer formed on the first interlayer dielectric layer and formed of a material layer identical with the spacers;
a second interlayer dielectric layer formed on the etch-stop layer; and
metal lines formed to penetrate the second interlayer dielectric layer and the etch-stop layer and coupled to the contact plugs, respectively.

7. The semiconductor device of claim 6, wherein:
the spacers and the etch-stop layer are formed of a nitride layer, and
the second interlayer dielectric layer is formed of an oxide layer.

8. The semiconductor device of claim 6, wherein the semiconductor substrate includes drain regions of a NAND flash memory device in which impurities are implanted,
wherein the metal lines are bit lines of the NAND flash memory device.

9. The semiconductor device of claim 5, wherein:
each of the barrier metal layers has a stack structure of a titanium (Ti) layer and a titanium nitride (TiN) layer, and
the conductive layers are each formed of a metal layer.

10. The semiconductor device of claim 9, wherein the metal layer of each conductive layer includes tungsten (W).

11. A semiconductor device, comprising:
a first layer formed over a semiconductor substrate;
holes formed to penetrate the first layer;
conductive layer formed within the holes; and
spacers formed between the conductive layer and sidewalls of the holes, wherein the spacers do not cover lower portions of the sidewalls of the holes.

12. The semiconductor device of claim 11, further comprising metal lines formed over the conductive layer, respectively, to contact the conductive layer and the spacers.

13. The semiconductor device of claim 11, further comprising a second layer formed over the first layer, wherein the second layer do not cover the conductive layer and are formed with a material identical with the spacers.

14. A method of manufacturing a semiconductor device, comprising:
forming a first interlayer dielectric layer on a semiconductor substrate;
forming contact holes penetrating the first interlayer dielectric layer;
forming contact plugs within the contact holes, wherein upper sidewalls of the contact plugs are recessed; and
forming spacers partially covering the upper sidewalls of the contact plugs.

15. The method of claim 14, wherein the forming of the contact plugs comprises:
forming a barrier metal layer on a surface of the first interlayer dielectric layer and the contact holes;
forming a conductive layer on the barrier metal layer to fill the contact holes with the conductive layer;
polishing the barrier metal layer and the conductive layer so that the first interlayer dielectric layer is exposed; and
forming recess regions by etching part of the barrier metal layers.

16. The method of claim 15, wherein:
the barrier metal layer has a stack structure of a titanium (Ti) layer and a titanium nitride (TiN) layer, and
the conductive layer includes tungsten (W).

17. The method of claim 16, wherein the forming of the recess regions includes etching the barrier metal layers using an etch gas formed of a mixture of BCl₃ and Cl₂ or a Cl₂ etch gas.

18. The method of claim 14, wherein the forming of the spacers includes forming an etch-stop layer on the first interlayer dielectric layer by forming a material layer on the first interlayer dielectric layer so that the recessed regions of the contact plugs are filled with the material layer and the material layer has a different etch selectivity with respect to the first interlayer dielectric layer.

19. The method of claim 18, further comprising:
forming a second interlayer dielectric layer on the etch-stop layer; and
forming metal lines coupled to the contact plugs through the second interlayer dielectric layer and the etch-stop layer, after forming the etch-stop layer.

20. The method of claim 19, wherein:
the material layer is formed of a nitride layer, and
the first and the second interlayer dielectric layers are formed of an oxide layer.

21. The method of claim 19, wherein the forming of the metal lines comprises:
etching the second interlayer dielectric layer so that the etch-stop layer is exposed;
etching the exposed regions of the etch-stop layer so that the contact plugs are exposed; and
filling the etched regions of the second interlayer dielectric layer and the etch-stop layer with a conductive material.

22. The method of claim 21, wherein the material layer is partially formed on the upper sidewalls of the contract plugs and the etching of the exposed regions of the etch-stop layer is performed so that the material layer formed the upper sidewalls of the contact plugs remains intact after the etching of the exposed regions of the etch-stop layer.

23. The method of claim 14, further comprises: forming select lines and word lines over the semiconductor substrate; and
forming junctions by implanting impurities into the semiconductor substrate between the adjacent select lines before the forming a first interlayer dielectric layer.
